(19) United States
(12) Patent Application Publication
(10) Pub. No.: US 2002/0167997 A1
(43) Pub. Date: Nov. 14, 2002

(54) Method of compensating signal distortion of one-tap equalizer bank for the orthogonal frequency division multiplexing system

(75) Inventors: Ki Seon Kim, Kwangju (KR); Hong Ku Kang, Kwangju (KR)

Correspondence Address: BACON & THOMAS, PLLC, 625 SLATERS LANE, FOURTH FLOOR, ALEXANDRIA, VA, 22314

(73) Assignee: Kwangju Institutes Of Science and Technology, Kwangju (KR)

(21) Appl. No.: 09/903,527

(22) Filed: Jul. 13, 2001

(30) Foreign Application Priority Data
Feb. 7, 2001 (KR) 5889

(51) Int. Cl. H03H 7/30

(52) U.S. Cl. 375/229; 370/208

(57) ABSTRACT

The present invention relates to an orthogonal frequency division multiplexing(OFDM) system.

The present invention presents a method of compensating the subcarrier signal distortion in an OFDM system caused by multi-path fading channels by using one-tap equalizer bank, which compensates the signal distortion with remarkably reduced system complexity compared with the prior art by introducing simplified calculation procedures of calculating a tap-value of an equalizer for one subcarrier using the tap-values of the equalizers for adjacent subcarriers.

### BACKGROUND OF THE INVENTION

1. Field of the Invention

The present invention relates to an orthogonal frequency division multiplexing(OFDM) system, and more particularly relates to an one-tap equalizer bank, which is used for compensating the signal distortion caused by multi-path fading channels in an OFDM system, having reduced structural complexity.

2. Description of the Related Art

OFDM is a multi-carrier transmission method that is effectively using the band-width by using a spectrum superposition. In contrast with the general single-carrier transmission method, which transmits high-speed data by serial transmission, OFDM transforms high-speed data into low-speed parallel data and transmits them thereafter. As a result, it reduces the interference between adjacent transmission symbols in a multi-channel system and performs a high-speed transmission easily.

Unlike in a serial transmission method in which interference between adjacent symbols occurs, the fading effect caused by multi-channels appears to be a distortion of transmission signal in an OFDM system. And the distortion of transmission signal caused by multi-path fading can be compensated easily compared with the case of a serial transmission method.

In an OFDM system, the signal distortion as described above is generally compensated by one of the two different methods as follows:

One is a differential modulation/demodulation method that transmits information of transmission data by transmitting only the difference between two symbols.

The differential modulation/demodulation method has an advantage that it is easily achieved because it codes the transmission data by using appropriate operations and memories and transmits them. However, it has disadvantages that an error of a symbol causes errors of two symbols and it has a weak noise-resistance.

To overcome these disadvantages mentioned above, a coherent modulation/demodulation method having one-tap equalizer bank is used.

A coherent modulation/demodulation method has more complicated structure than a differential modulation/demodulation method, however, its performance is about twice as good as that of a differential modulation/demodulation method.

Even though a coherent modulation/demodulation method having one-tap equalizers has a complicated structure, the development of semiconductor design and integration technology has made it possible to accomplish a coherent modulation/demodulation method having a complicated one-tap equalizer bank.

However, since the number of required one-tap equalizers in the prior art is the same as the number of subcarriers, as the number of subcarriers used in the system increases and the complexity of the algorithm to calculate the tap-values of equalizers increases, the design of a coherent modulation/demodulation method having one-tap equalizer bank becomes very difficult. What is worse, it becomes to be unachievable in some cases.

### SUMMARY OF THE INVENTION

The present invention is proposed to solve the problems of the prior art mentioned above. It is therefore the object of the present invention to provide an one-tap equalizer bank applicable for introducing a coherent modulation/demodulation method to an OFDM system, which reduces the system structural complexity with maintaining the system efficiency, and make it easy to establish an OFDM system thereby.

To achieve the object mentioned above, the present invention presents a method of compensating signal distortion, which obtains tap-values by a simple calculation using the fact that the characteristics of adjacent subcarrier channels are similar to each other in an OFDM system, pre-estimates the channels by an interpolation using these adjacent tap-values, and accomplishes a coherent modulation/demodulation method having one-tap equalizer bank without a large increase of the system complexity thereby.

### BRIEF DESCRIPTION OF THE DRAWINGS

FIG. 1 is a diagram illustrating the structure of a general OFDM system.

FIG. 2 is a diagram illustrating linear interpolation procedures in accordance with the present invention.

FIG. 3 is a diagram illustrating the structure of an one-tap equalizer bank in accordance with the present invention.

FIG. 4 is a graph comparing bit error rates of an embodiment (LMS) of the present invention and those of the prior art along with frequency offset values.

FIG. 5 is a graph comparing bit error rates of another embodiment(RLS) of the present invention and those of the prior art along with channel condition.

### DESCRIPTION OF THE NUMERAL ON THE MAIN PARTS OF THE DRAWINGS

10: a transmitter

20: a channel

30: a receiver

40: an adder

50: a multiplier

60: a full adder

### DETAILED DESCRIPTION OF THE EMBODIMENTS

Hereinafter, referring to appended drawings, the structure and the operation procedures of one-tap equalizer bank in an OFDM system proposed in accordance with the present invention is described in detail.

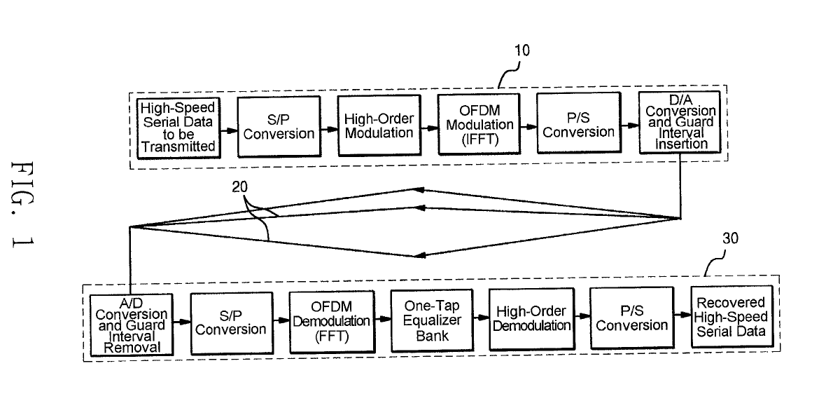

FIG. 1 shows a typical system model of an OFDM system employing a coherent modulation/demodulation method having one-tap equalizer bank. The system is mainly composed of a transmitter(10), channels(20), and a receiver(30).

Referring to FIG. 1, the high-speed serial data symbols input to the transmitter(10) are first transformed into low-speed parallel data symbols by a series/parallel(S/P) converter, and modulate subcarriers through an inverse fast Fourier transform(IFFT) algorithm thereafter.

With a guard interval being inserted, the modulated data symbols are converted to analog signals, which are fit for the transmission, and transmitted.

Here, the complex amplitude of an OFDM signal transmitted from the transmitter(10) can be calculated by the following equation:

$$s ( t ) = {\sum }_{n = - ∞}^{∞} {\sum }_{k = 0}^{N - 1} \sqrt{\frac{A}{T}} {a}_{n , k} {ⅇ}^{j2π ( {f}_{k} + {f}_{c} ) t} p ( t - n T ) . \qquad \text{Equation 1}$$

Here, N is the number of subcarriers, A is a constant related to the electric power of a signal, T is the length of an OFDM signal including the guard interval, a_{a,k} is the data symbol transmitted on k-th subcarrier at n-th time interval, fₖ is the frequency of k-th subcarrier, f_{c} is the frequency of carrier, and p(t) represents a spherical pulse of which the amplitude is 1 and the length is T.

The OFDM transmission signal described in Equation 1 is transmitted to the receiver(30) through multi-path channels(20).

The channels(20) employed in the present invention are two-path channels(20) having one for a direct wave through a direct path and the other for a reflection wave representing numbers of delayed paths.

An impulse response of a channel(20) can be described by the following equation:

h(t)=[δ(t)|αδ(t τ)]. Equation 2

Here, α is an attenuation coefficient of a delayed path having Rayleigh distribution, and τ is delayed time having normal distribution smaller than protection block.

After the signals through the multi-path channels(20) are received at the receiver(30), the protection blocks inserted at the transmitter(10) are eliminated and the subcarrier demodulation is carried out by using a fast Fourier transform(FFT).

Here, a demodulated k-th subcarrier signal is the sum of transmission signal distorted by multi-path fading and white noise, which can be described by the following equation:

u_{n,k}=\sqrt{A}α_{n,k[}1+αe^{-j2π(ƒ}^{_{c}}^{+ƒ}^{ₖ}^{)τ]}+N_{n,k}. Equation 3

Here, N_{n,k} is a noise component caused by white noise.

Referring to the part representing the distortion of k-th signal by multi-path channels(20), [1+αe^{-j2π(ƒ}^{_{c}}^{+ƒ}^{ₖ}^{)τ}], in Equation 3, one can find that the phase is e^{-j2π(ƒ}^{_{c}}^{+ƒ}^{ₖ}^{)τ}.

If the value of frequency division band(fₖ−fₖ₋₁) between subcarriers is considerably smaller than delayed time(τ), the signal distortions in adjacent subcarriers are given by similar values.

The present invention takes advantage of the characteristic that the signal distortions in adjacent subcarriers are given by similar values.

One-tap equalizer bank is used for compensating the signal distortion in an OFDM system, and the value of one-tap equalizer bank is approximately given by the inverse value of the signal distortion in each subcarrier.

The fact that the values of signal distortions in adjacent subcarriers are similar to each other intuitively means that the tap-values of two adjacent one-tap equalizers are similar to each other. Therefore, using a tap-value of an equalizer for one subcarrier, the tap-value of the equalizer for the adjacent subcarrier can be calculated.

There are numbers of possible algorithms to calculate the tap-value of one equalizer for a subcarrier by using the tap-values of other equalizers for the adjacent subcarriers. To avoid an arithmetic complexity, the present invention introduces a simple interpolation method as described by the following equation:

Cₖ=ƒ(Cₖ₋₁,Cₖ₊₁). Equation 4

Here, Cₖ is tap-value of the equalizer for k-th subcarrier.

For an example of a simple interpolation method, the tap-value can be calculated by a linear interpolation as described by the following equation:

$${C}_{k} = \frac{{C}_{k - 1} + {C}_{k + 1}}{2} . \qquad \text{Equation 5}$$

As described above, the tap-value of an equalizer for a certain subcarrier can be simply calculated from the tap-values of the equalizers for two adjacent subcarriers by using a linear interpolation method.

In addition, the system complexity can be reduced because the linear interpolation method can be accomplished by using only one full-adder(60) in the system.

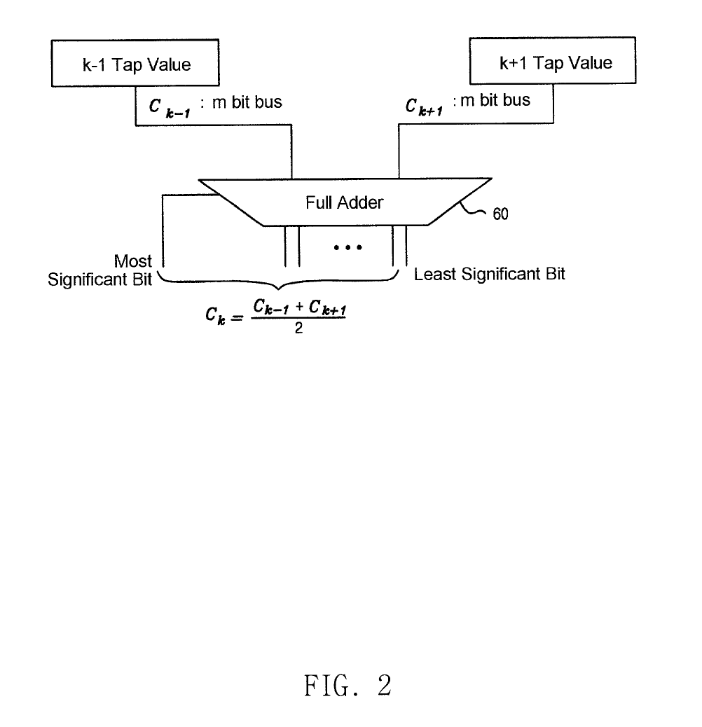

FIG. 2 is a diagram illustrating an embodiment of a linear interpolation method using one full-adder.

In the linear interpolation method described in the figure, addition is carried out by a full-adder(60) and division can be carried out by using a wired shift operation, which moves the output of the full adder(60) to 1-bit to the right. Therefore, the system can be accomplished without an additional increase of complexity.

As described above, by introducing an one-tap equalizer bank using a linear interpolation method, one-tap equalizers corresponding to about half of numbers of subcarriers can be accomplished by using one full-adder and one multiplier.

Therefore, compared with the prior art using a complicated algorithm, the present invention can reduce the complexity of the receiver(30) remarkably.

In addition, since the algorithm described above is independent of the algorithm to calculate tap-values and uses the calculated tap-values only, it is applicable to various equalizer banks using different calculation algorithms. Consequently, it provides flexibility and convenience in system embodiment.

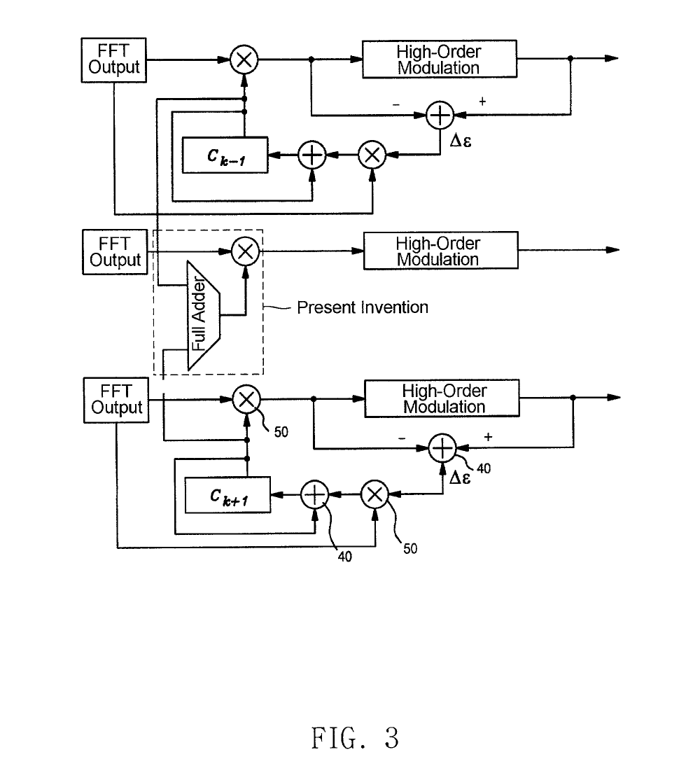

FIG. 3 is a diagram illustrating the structure of some part of an equalizer bank of an OFDM receiver(30) using an one-tap equalizer bank in accordance with the present invention.

In FIG. 3, a least mean square(LMS) algorithm, which is able to calculate tap-values from the values of adjacent subcarriers by comparably simple operations, is used to illustrate the extent of complexity reduced by employing an equalizer bank in accordance with the present invention.

Even though using a simple LMS algorithm, the prior equalizer bank requires adders and multipliers two times as many as the number of subcarriers, and it requires memories, as many as the number of subcarriers, to store the tap-values. In the case of employing an equalizer bank in accordance with the present invention, however, it only requires adders and multipliers of about one and half of numbers of subcarriers, and memories of half of numbers of subcarriers.

Therefore, the present invention can reduce the number of adders, multipliers, and memories by about half of the number of subcarriers.

This implies that, in an OFDM system using a considerably large number of subcarriers, if using an one-tap equalizer bank in accordance with the present invention, the system can be accomplished more easily compared with the system using the prior one-tap equalizer bank.

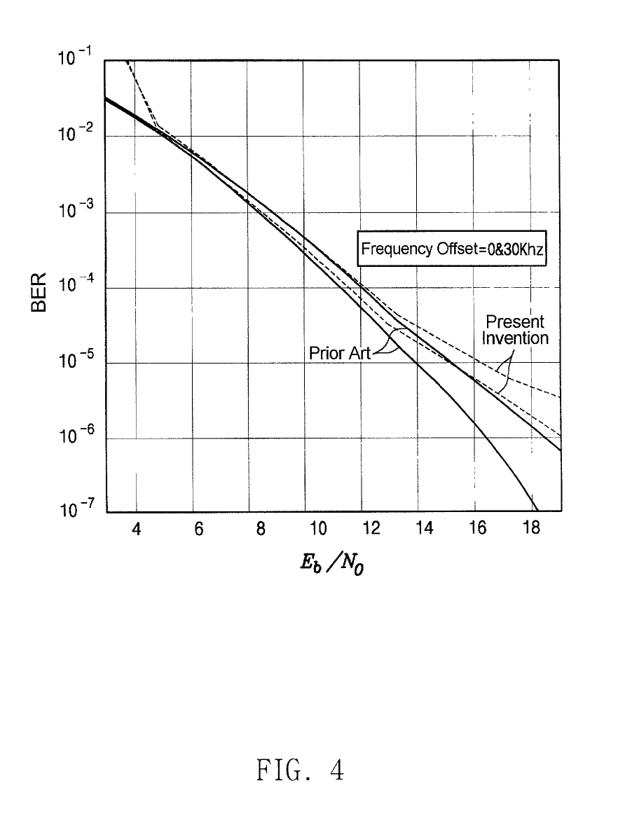

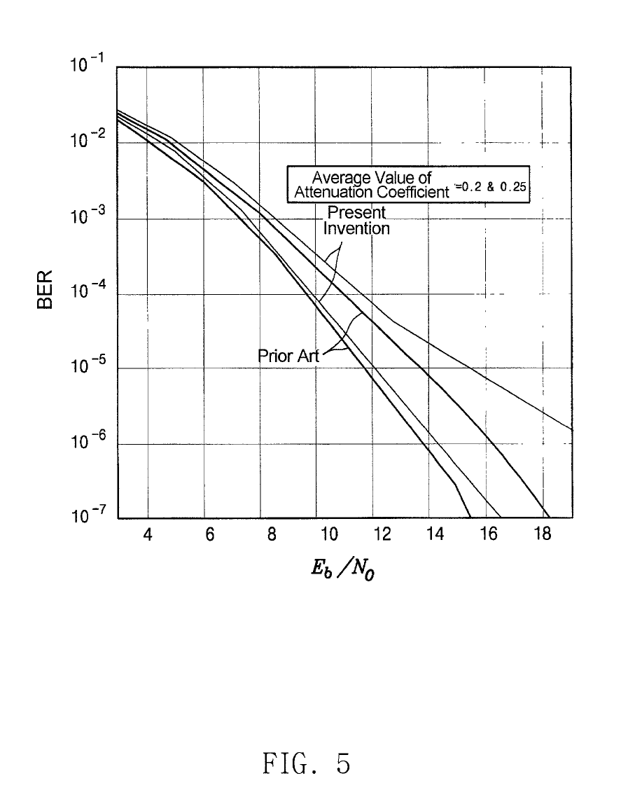

FIG. 4 and FIG. 5 are graphs comparing bit error rates(BERs) of an OFDM system using an equalizer bank in accordance with the present invention and those of an OFDM system using the prior equalizer bank.

Here, the number of subcarriers is assumed to be 128, and the values of parameters of a typical millimeter-wave channel are used. A probabilistic variable having Rayleigh distribution is used for the attenuation coefficient(α) of delayed path, and a probabilistic variable having uniform distribution smaller than the guard interval is used for delayed time(τ).

FIG. 4 shows a comparing result of bit error rates of an OFDM system in accordance with the present invention using an LMS algorithm and those of an OFDM system of the prior art using an LMS algorithm in case that the average of attenuation coefficients is 0.25.

Looking at the BEP value of 10⁻³, which is generally used in many cases, it is noticed that the efficiency of the present invention is slightly lower than that of the prior art. However, as shown in the figure, the efficiency of the system in accordance with the present invention is almost the same as that of the prior art even in the case that 30 KHz of frequency offset exists.

Considering the complexity of one-tap equalizer bank, an OFDM system using an one-tap equalizer bank in accordance with the present invention is much easier to be designed and accomplished compared with the prior art. Conclusively, the present invention provides an OFDM system that can reduce the system complexity remarkably without any noticeable degradation in its efficiency compared with the prior art.

FIG. 5 shows a comparing result of bit error rates of an OFDM system in accordance with the present invention using a recursive least square(RLS) algorithm and those of an OFDM system of the prior art using an RLS algorithm.

Looking at the BER value of 10⁻³, it is also noticed that the efficiency of the present invention is very slightly lower than that of the prior art.

This verifies that the present invention is applicable to an RLS algorithm as well as an LMS algorithm. Moreover, since the present invention is independent of tap-value calculation algorithm, it is applicable to various types of different algorithms.

In addition, looking at the cases that the average value of attenuation coefficients is 0.2 and 0.25, it is also noticed that the efficiency of the present invention is almost the same as that of the prior art.

This verifies that the present invention is applicable to the systems having various channel conditions.

As mentioned thereinbefore, an one-tap equalizer bank in accordance with the present invention simplifies the structure of OFDM system without any noticeable degradation in its efficiency compared with the prior art by enabling to accomplish numbers of—about half the number of subcarriers—one-tap equalizers using a simple interpolation method.

In addition, since the structure of an one-tap equalizer in accordance with the present invention is independent of the algorithm to calculate tap-values of an equalizer, it is applicable to various types of equalizer banks using different calculation algorithms. As a result, it provides flexibility and convenience in OFDM system design.

Since those having ordinary knowledge and skill in the art of the present invention will recognize additional modifications and applications within the scope thereof, the present invention is not limited to the embodiments and drawings described above:

What is claimed is:

1. A method of compensating signal distortion of one-tap equalizer bank for an orthogonal frequency division multiplexing(OFDM) system, which compensates the subcarrier signal distortion in an OFDM system caused by multi-path fading channels by using one-tap equalizer bank, characterized by:
compensating the signal distortion by calculating a tap-value of an equalizer for one subcarrier using the tap-values of the equalizers for adjacent subcarriers.

2. A method of compensating signal distortion of one-tap equalizer bank for an OFDM system as claimed in claim 1,
wherein said tap-value of an equalizer is calculated by the following equation:
Cₖ=ƒ(Cₖ₋₁, Cₖ₋₁), Equation 6
where, Cₖ is tap-value of an equalizer for k-th subcarrier.

3. A method of compensating signal distortion of one-tap equalizer bank for an OFDM system as claimed in claim 1 or 2,
wherein said tap-value of an equalizer is calculated by a linear interpolation method expressed by the following equation:
$${C}_{k} = \frac{{C}_{k - 1} + {C}_{k + 1}}{2} , \qquad [ Equation 7 ]$$
where, Cₖ is tap-value of an equalizer for k-th subcarrier.

4. A method of compensating signal distortion of one-tap equalizer bank for an OEDM system as claimed in claim 3,
wherein said linear interpolation method is characterized in that:
addition is carried out by a full-adder; and
division is carried out by a wired shift operation, which moves the output of the full adder to 1-bit to the right.
